(19) United States
(12) Patent Application Publication
(10) Pub. No.: US 2017/0069686 A1
(43) Pub. Date: Mar. 9, 2017

(54) MEMORY DEVICE AND METHOD OF MANUFACTURING THE SAME

(71) Applicant: Keisuke NAKATSUKA, Seoul (KR)

(72) Inventor: Keisuke NAKATSUKA, Seoul (KR)

(21) Appl. No.: 14/945,178

(22) Filed: Nov. 18, 2015

Related U.S. Application Data
(60) Provisional application No. 62/215,752, filed on Sep. 9, 2015.

(51) Int. Cl. H01L 27/22; H01L 29/66; G11C 11/16; H01L 43/12; H01L 43/02; H01L 43/08

(52) U.S. Cl. CPC H01L 27/228; H01L 43/02; H01L 43/08; G11C 11/161; H01L 43/12; H01L 29/66477

(57) ABSTRACT

A memory device of one embodiment includes a substrate; a first conductor above the substrate; a first transistor whose one of a source and a drain is coupled to the first conductor; a memory element which is provided above a top of the first conductor, has one of switchable resistances, and is coupled at a first end to the other of the source and the drain of the first transistor; and a second transistor which is provided above the substrate and has a gate electrode having a height lower than a top of the first conductor.

### CROSS-REFERENCE TO RELATED APPLICATIONS

This application claims the benefit of U.S. Provisional Application No. 62/215,752, filed Sep. 9, 2015, the entire contents of which are incorporated herein by reference.

### FIELD

Embodiments relate to a memory device.

### BACKGROUND

Memory devices using a magnetoresistive effect are known.

### BRIEF DESCRIPTION OF THE DRAWINGS

FIG. 1 illustrates functional blocks of a memory device of one embodiment;

FIG. 2 is a circuit diagram of an example of a memory cell of the memory device of one embodiment;

FIG. 3 illustrates an example of the structure of a variable resistance element of the memory device of one embodiment;

FIG. 4 illustrates a view of a part of the memory device of one embodiment when seen from above;

FIG. 5 illustrates a view of a part of the memory device of one embodiment when seen from above;

FIG. 6 illustrates a cross section of the memory device of one embodiment;

FIG. 7 illustrates a cross section of the memory device of one embodiment in one state in the process of manufacture;

FIG. 8 illustrates the cross section of the memory device in the state after FIG. 7;

FIG. 9 illustrates the cross section of the memory device in the state after FIG. 8;

FIG. 10 illustrates the cross section of the memory device in the state after FIG. 9;

FIG. 11 illustrates the cross section of the memory device in the state after FIG. 10;

FIG. 12 illustrates the cross section of the memory device in the state after FIG. 11;

FIG. 13 illustrates the cross section of the memory device in the state after FIG. 12;

FIG. 14 illustrates the cross section of the memory device in the state after FIG. 13;

FIG. 15 illustrates a cross section of the structure of a memory device for reference; and

FIG. 16 illustrates a cross section of the structure of another memory device for reference.

### DETAILED DESCRIPTION

According to one embodiment, a memory device includes a substrate; a first conductor above the substrate; a first transistor whose one of a source and a drain is coupled to the first conductor; a memory element which is provided above a top of the first conductor, has one of switchable resistances, and is coupled at a first end to the other of the source and the drain of the first transistor; and a second transistor which is provided above the substrate and has a gate electrode having a height lower than a top of the first conductor.

Embodiments will now be described with reference to the figures. In the following description, components with substantially the same functionalities and configurations will be referred to with the same reference numerals, and repeated descriptions are omitted. The figures are schematic, and the relationship between the thickness and the area of a plane of a layer and the ratios of layer thicknesses may differ from the actual ones. Moreover, the figures may include components which differ in relationships and/or dimension ratios in different figures. An embodiment only illustrates devices and methods for materializing the technical idea of this embodiment, and the technical idea of the embodiments do not specify the quality of the material, form, structure, arrangement of components, etc. to the following.

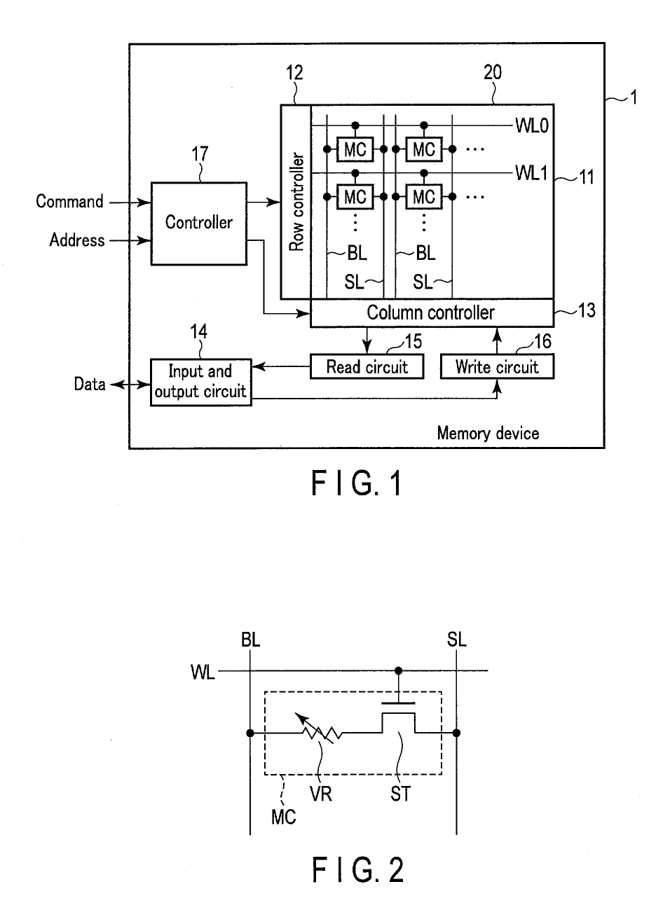

FIG. 1 illustrates functional blocks of a memory device of one embodiment. The memory device 1 includes components, such as a memory cell array 11, a row controller 12, a column controller 13, an input and output circuit 14, a read circuit 15, a write circuit 16, and a controller 17.

The memory cell array 11 includes plural memory cells MC. The memory cell array 11 is provided with bit lines BL, source lines SL, and word lines WL therein. A memory cell MC includes at least a variable resistance element. The variable resistance element can take one of resistance states with different magnitudes. The memory device 1 is, for example, a magnetoresistive random access memory (MRAM), and one memory cell MC includes a variable resistance element VR and a select transistor ST as illustrated in FIG. 2. The variable resistance element VR and the select transistor ST are coupled in series between a pair of a bit line BL and a source line SL.

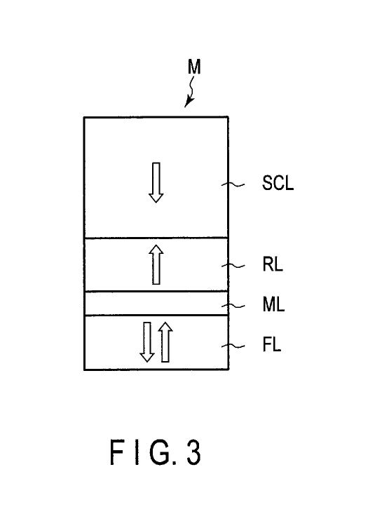

The gate of the select transistor ST is coupled to one word line WL. The variable resistance element VR includes, for example, a magnetoresistive effect element, and the magnetoresistive effect element includes, for example, a magnetic tunnel junction (MTJ) element M, as illustrated in FIG. 3. The MTJ element M includes a reference layer RL of a magnetic material and a storage layer FL of a magnetic material, and a nonmagnetic layer ML therebetween. The orientation of magnetization of the storage layer FL (illustrated by arrows) is variable. The orientation of magnetization of the reference layer RL is invariable, and has a larger coercivity than the coercivity of the storage layer FL, for example. The MTJ element M exhibits the minimum and maximum resistances when the orientation of the magnetization of the reference layer RL and the orientation of magnetization of the storage layer FL are parallel and anti-parallel, respectively. When a current flows through the reference layer RL and the storage layer FL, the storage layer FL may have its magnetization orientation switched based on the direction of the current. That the magnetization orientation of the reference layer is “invariable” indicates that the magnetization orientation of the reference layer RL does not switch by a current of a magnitude that is able to switch the magnetization orientation of the storage layer FL.

The MTJ element M further includes a shift control layer SCL. The shift control layer SCL and the nonmagnetic layer ML sandwich the reference layer RL. The orientation of the magnetization of the shift control layer SCL does not switch by a current of a magnitude which may switch the magnetization orientation of the storage layer FL, and the shift control layer SCL has a coercivity larger than the coercivity of the reference layer RL, for example. The shift control layer SCL has the magnetization oriented anti-parallel to the magnetization orientation of the reference layer RL. The magnetic field formed by the shift control layer SCL offsets the magnetic field formed by the reference layer RL, and can suppress the magnetization orientation of the storage layer FL from being fixed to be parallel with the magnetization orientation of the reference layer RL by the magnetic field formed by the reference layer RL.

Referring back to FIG. 1, the controller 17 receives control signals, such as addresses and commands, from the outside, and controls the row controller 12, the column controller 13, the read circuit 15, and the write circuit 16 based on the control signals. The row controller 12 receives a row address from the controller 17, and selects one word line WL based on the received row address. The column controller 13 receives a column address from the controller 17, and selects one pair of a bit line BL and a source line SL based on the column address. The read circuit 15 reads data stored in the selected memory cell MC to the input and output circuit 14. The write circuit 16 conducts a write current through the selected memory cell MC to write specified data. The input and output circuit 14 transmits write data input from the outside to the write circuit 16, and outputs read data from the read circuit 15 to the outside.

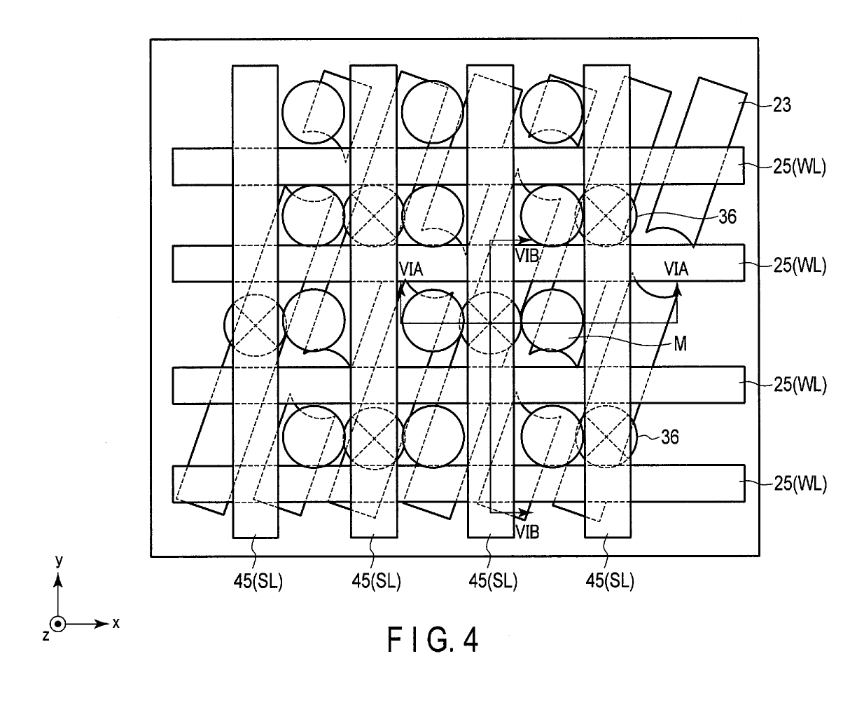

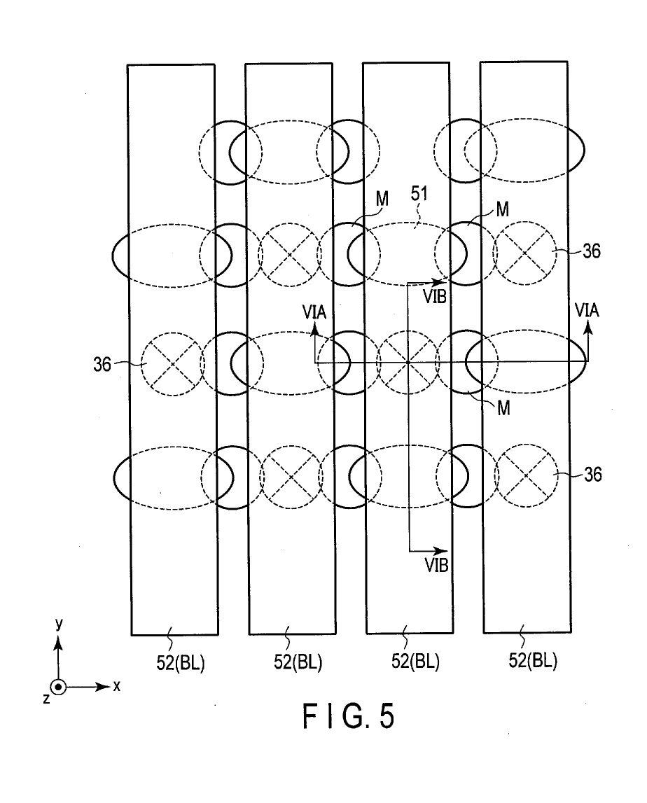

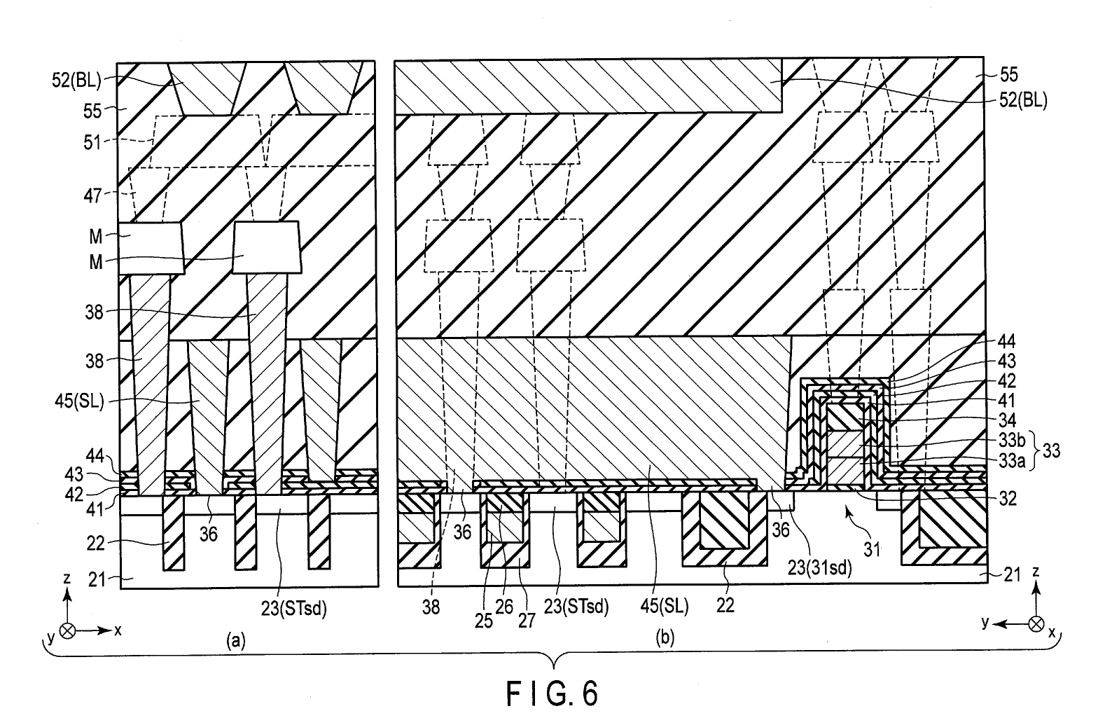

FIGS. 4 to 6 illustrate parts of the structure of the memory device according to one embodiment. FIG. 4 illustrates a view of the cell array 11 when seen from above. FIG. 4 illustrates components between the lowest position and a particular position along the z-axis. FIG. 5 illustrates components along the z-axis above the plane of FIG. 4. FIG. 6 illustrates cross sections of the structure of a part of the cell array 11 and a part of an area other than the cell array 11. The area other than the cell array 11 includes the row controller 12, the column controller 13, the input and output circuit 14, the read circuit 15, the write circuit 16, and the controller 17, and it is referred to as a peripheral area hereinafter. FIG. 6(a) illustrates the cross section along the VIA-VIA line of FIGS. 4 and 5, and FIG. 6(b) illustrates the cross section along the VIB-VIB line of FIGS. 4 and 5 and the cross section of a part of the peripheral area. A component of a dashed line is located in a section other than the illustrated cross section.

As illustrated in FIGS. 4 to 6, the memory device 1 includes a substrate 21 of, for example, silicon. The plane of the substrate 21 along the xy-plane is provided with element isolation insulators 22. The insulators 22 surround active areas 23 and separate the active areas 23 from each other. Each active area 23 has a linear shape, for example, and extends along the xy-plane and orthogonally to the y-axis and x-axis.

The surface of the substrate 21 is provided with plural conductors 25. Each conductor 25 serves as a word line WL, and may be referred to as a word line conductor 25 hereinafter. The conductors 25 are located in the substrate 21, and have their tops covered with insulators 26. The side of each set of a conductor 25 and an insulator 26, and the bottom of the insulator 26, are covered with an insulator 27. The sets of the conductor 25 and the insulators 26 and 27 extend, for example, along the x-axis through the insulators 22 and the active area 23, and have an interval along the y-axis.

The surface of the substrate 21 in the active area 23 is provided with a transistor 31. The transistor 31 forms a part of a circuit in the peripheral area. The transistor 31 includes a gate insulator 32 on the substrate 21, a gate electrode 33 on the gate insulator 32, and source or drain areas 31sd in the active area 23. The gate electrode 33 includes a first section 33a on the gate insulator 32, and a second section 33b on the first section 33a. The first section 33a is, for example, conductive polysilicon, and the second section 33b is, for example, tungsten (W). A nitride 34 is provided on the second section 33b. The nitride 34 is a film of silicon nitride, for example. The set of the gate oxide 32, the gate electrode 33, and the nitride 34 is referred to as a gate structure hereinafter.

Plural conductive contacts (or, contact plugs) 36 are arranged along the xy-plane. Each contact 36 is in contact with one active area 23 at the bottom. The sections of the active areas below the contacts 23 are provided with layers of diffused impurities. The impurity diffusion layers serve as the source or drain areas STsd of the select transistors ST.

Plural lower electrodes 38 are arranged along the xy-plane. Each lower electrode 38 is in contact with an active area 23 at its bottom. The sections of the active areas 23 in contact with the lower electrodes 38 are provided with layers of diffused impurities. The impurity diffusion layers serve as the source or drain areas STsd of the select transistors ST. Two source or drain areas STsd in one active area at the both sides of one gate electrode, and the part of that gate electrode between those two source or drain areas STsd function as one select transistor ST. One of the two source or drain areas STsd of each select transistor ST is in contact with one contact 36, and the other is in contact with one lower electrode 38.

The surfaces of the element isolation insulators 22 and the substrate 21, and the side and the top of the gate structure are covered with an oxide 41. The oxide 41 surrounds the contacts 36 and the lower electrodes 38 along the xy-plane, and is, for example, a film of silicon oxide. The top of the oxide 41 is covered with a nitride 42. The nitride 42 surrounds the contacts 36 and the lower electrodes 38 along the xy-plane, and is, for example, a film of silicon nitride.

Conductors 45 are provided on the contacts 36 and the nitride 42. The conductors 45 serve as the source lines SL, extend in the yz-plane to have a plate shape, extend along the y-axis, and have an interval along the x-axis. The conductors 45 may be referred to as source line films 45 hereinafter. The tops of the source line films 45 are lower than the tops of the lower electrodes 38, and higher than the top of the gate electrode 33 of the transistor 31. The heights of the source line films 45 (or, the positons of the tops) are higher than, for example, twice the height of the gate electrode 33 (or, the top position). Each source line film 45 is a film of one layer, and in other words includes a material of substantially the same component between a first point in the top surface and a second point in the bottom surface. The first and second points are in line, for example, along the z-axis. Alternatively, the source line films 45 include a material of substantially the same components over its entirety. In addition or alternatively, the source line films 45 are films obtained by one process under a particular condition, i.e., a set of parameters used in the process for forming the films.

The source line films 45 have high aspect ratios. For example, the bottoms of the source line films 45 are preferably closer to the substrate 21. The bottoms of the source line films 45 face with the surface of the substrate 21 only with a very thin intervening film for forming the structure of FIG. 6, or for securing a required select ratio of etching rates. In the FIG. 6 example, the bottoms of the source line films 45 reach the nitride 42. As a result, the source line films 45 can have high aspect ratios. The specific aspect ratio of the source line films 45 is, for example, five or higher, and is between fifteen and thirty.

The source line films 45 are films of metal, and are material which does not cause disconnection of the source lines SL by breaking apart due to condensation of the molecules in an environment of a high temperature. Specifically, the material of the source line films 45 is a material which does not break apart in an environment in which the structure of the memory device under manufacture is placed for forming the MTJ elements M, which will be described later. In addition, the material is a material which can realize a low resistance required for the source lines SL. More specifically, the source line films 45 include tungsten or titanium nitride, or are films of tungsten or titanium nitride.

The surface of the nitride 42 is covered with an oxide 43. The surface of the oxide 43 is covered with a nitride 44. The oxide 43 and the nitride 44 are in contact with the sides of the source line films 45 along the xy-plane. The oxide 43 is, for example, a film of silicon oxide, and the nitride 44 is, for example, a film of silicon nitride. The oxide 43 and the nitride 44 surround the lower electrodes 38 and the source line films 45 along the xy-plane.

On each lower electrode, an MTJ element M is provided. An upper electrode 47 is provided on each MTJ element M. A second upper electrode 51 is provided on the tops of two upper electrodes which are in line along the x-axis without a contact 36 therebetween. Conductive films 52 are provided on the second upper electrodes 51. The conductive films 52 serve as the bit lines BL, extend along the y-axis, and have an interval along the x-axis. The area over the substrate 21 without components is covered with an insulator 55.

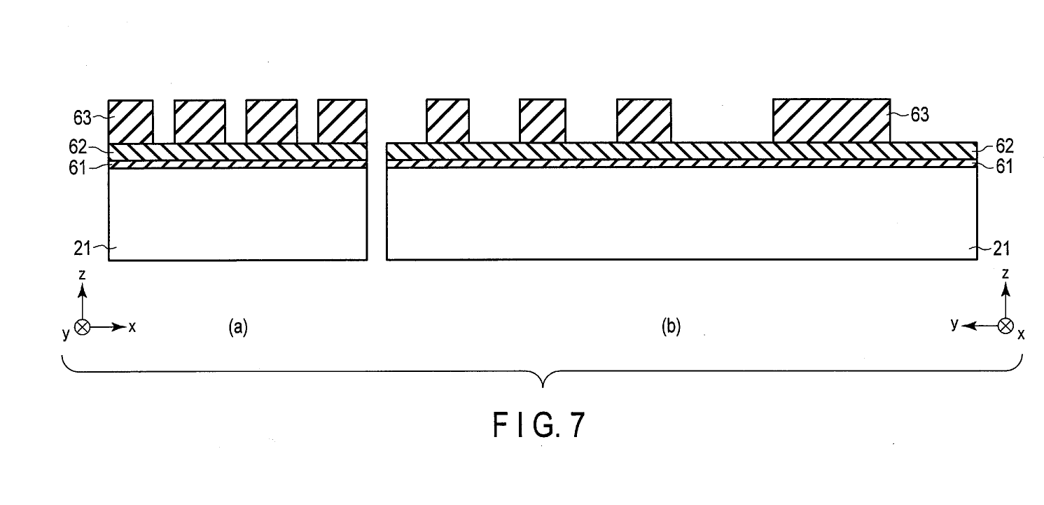

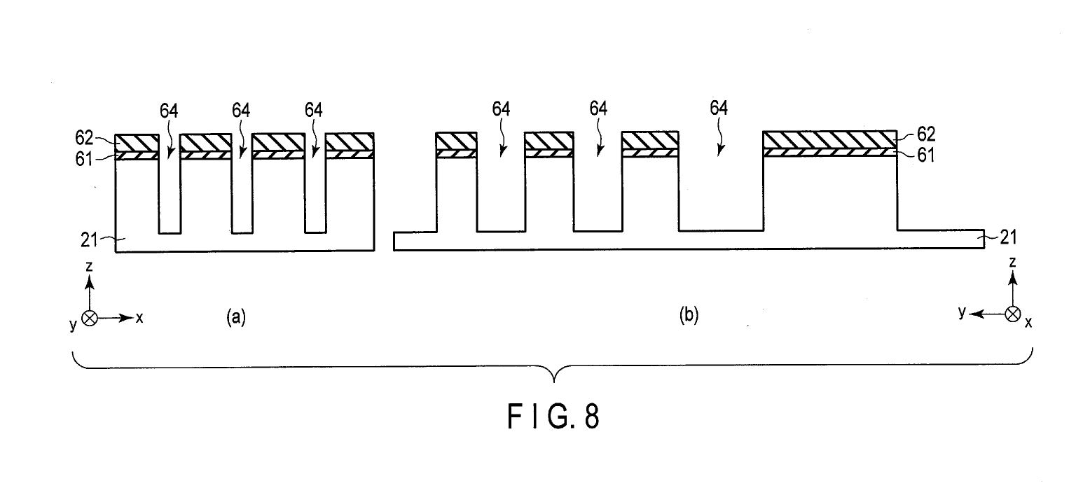

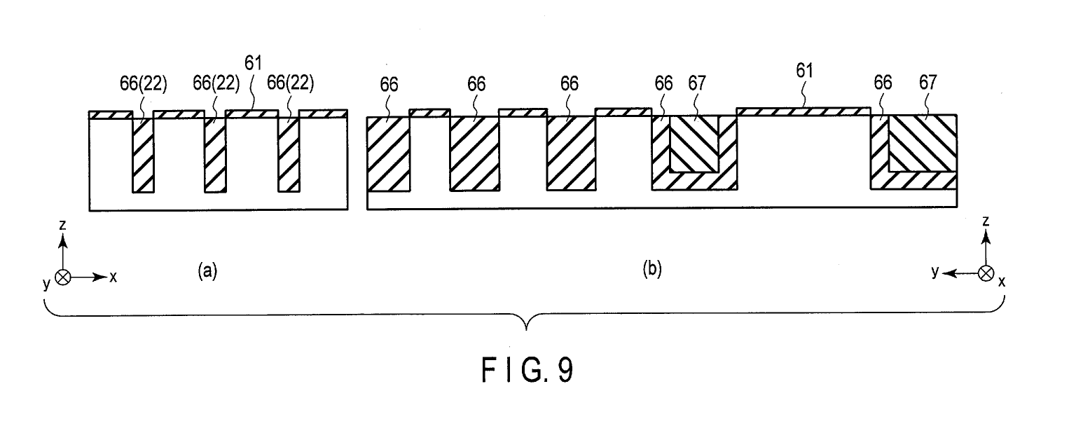

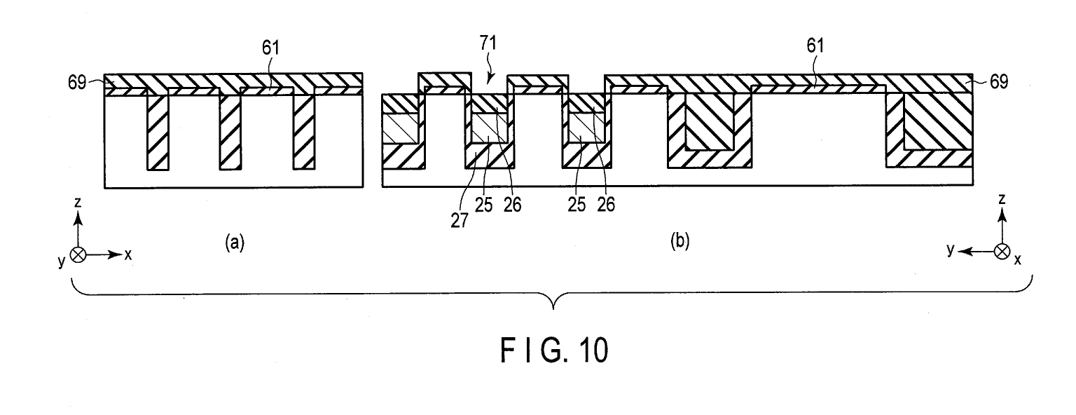

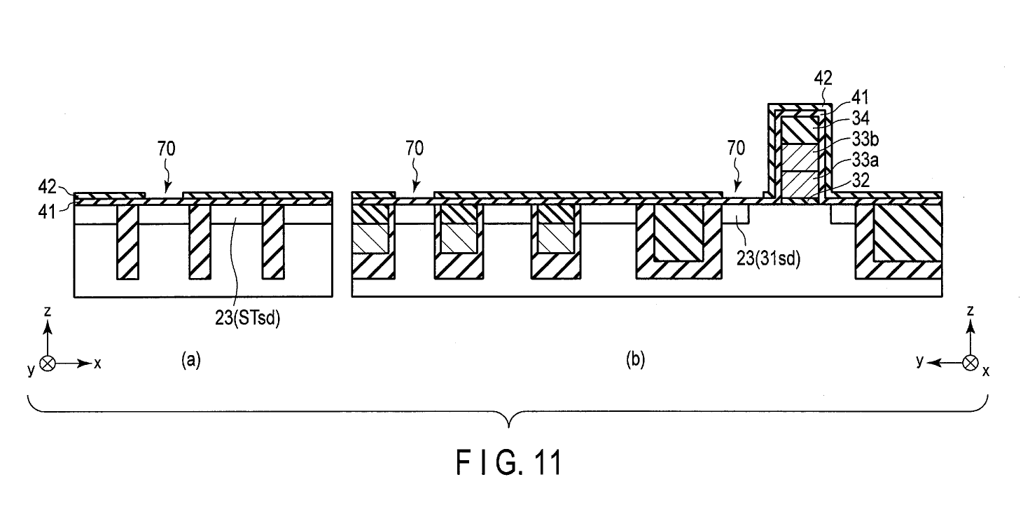

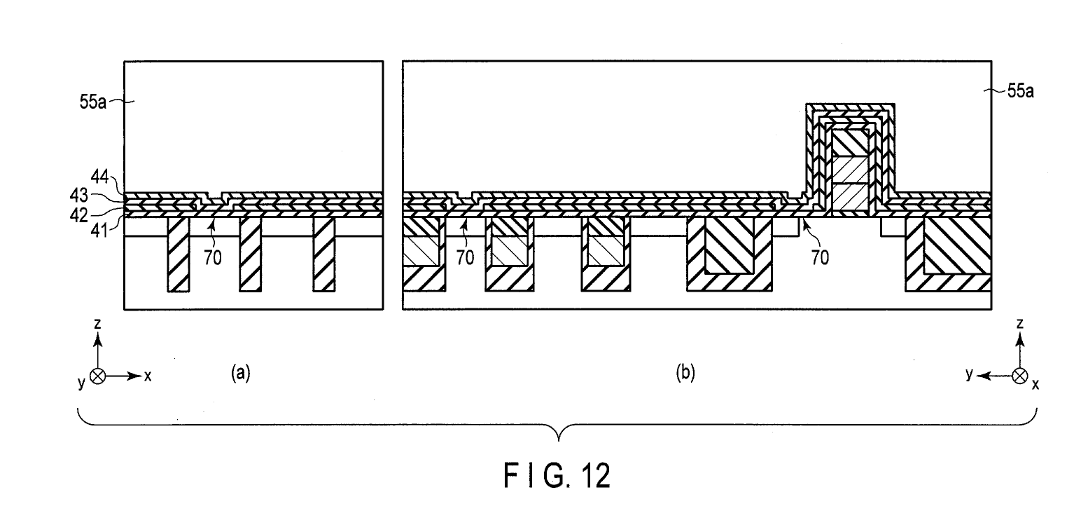

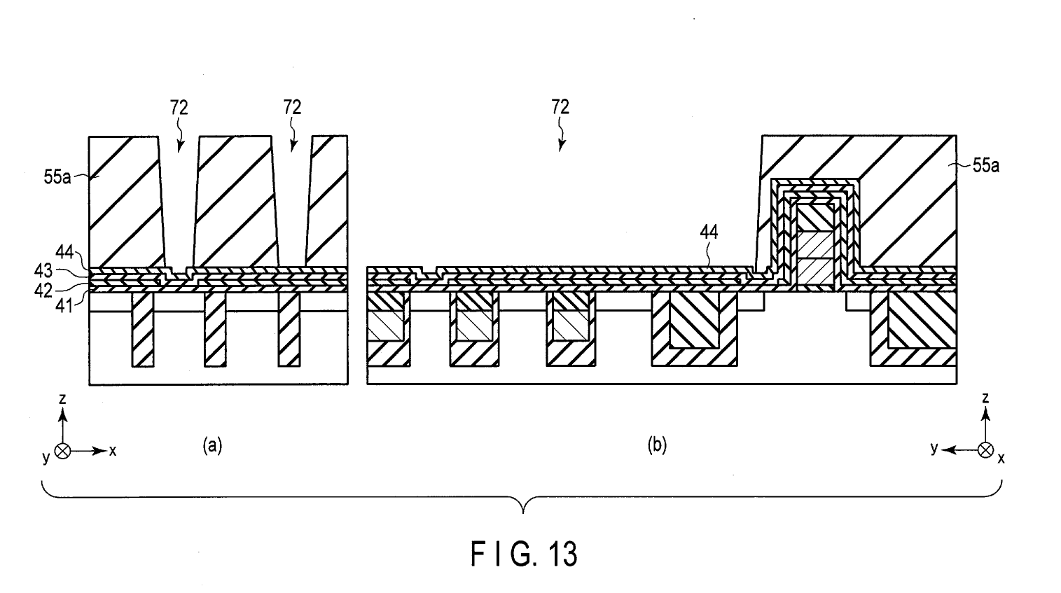

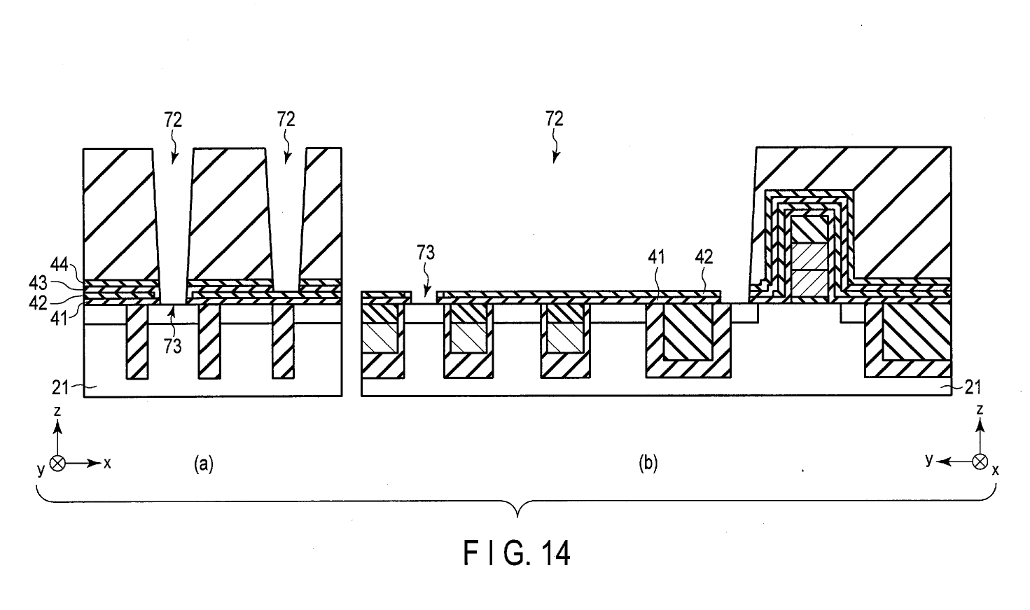

A description will now be given of an example of a method for forming the structure of FIGS. 4 to 6 with reference to FIGS. 6 to 14. FIGS. 7 to 14 illustrate states in the method for forming the structure of the memory device of one embodiment in order. FIG. 7(a), FIG. 8(a), FIG. 9(a), FIG. 10(a), FIG. 11(a), FIG. 12(a), FIG. 13(a), and FIG. 14 (a) illustrate the cross section along the VIA-VIA line of FIGS. 4 and 5. FIG. 7(b), FIG. 8(b), FIG. 9(b), FIG. 10(b), FIG. 11(b), FIG. 12(b), FIG. 13(b), and FIG. 14(b) illustrate the cross section along the VIB-VIB line of FIGS. 4 and 5.

As illustrated in FIG. 7, an oxide 61 is deposited on the whole surface of the substrate 21, and a nitride 62 is deposited on the oxide 61. The oxide 61 is, for example, a film of silicon oxide, and the nitride 62 is, for example, a film of silicon nitride. On the nitride 62, a film 63 is formed by deposition and a lithography process. The film 63 has holes where the element isolation insulators 22 and the gate electrodes 33 will be formed. The film 63 includes, for example, tetraethylorthosilicate (TEOS).

As illustrated in FIG. 8, the holes in the film 63 are copied to the films 62 and 61 by the reactive ion etching (RIE) with the film 63 used as a mask. Trenches 64 are then formed in the substrate 21 by, for example, the RIE with the films 62 and 61 used as a mask. The trenches 64 have shapes corresponding to the shapes of the holes of the films 63 along the xy-plane.

As illustrated in FIG. 9, an insulator 66 is deposited on the surfaces of the trenches 64. The insulator 66 buries the trenches 64 in FIG. 9(a) to serve as the element isolation insulators 22, and buries trenches 64 with small openings in FIG. 9(b). Insulators 67 are then deposited in the trenches 64 with large openings in FIG. 9(b). The insulators 67 are films of silicon on dielectric (SOD), for example. The nitride 62 is then removed and ions are implanted into areas where the channels of the select transistors ST will be formed through the oxide 61 to adjust the threshold voltages of the select transistors ST.

As illustrated in FIG. 10, the RIE with a mask 69 is used to remove sections of the insulators 66 where word line conductors 25 will be formed. In the removed sections, conductors are formed to make the word line conductors 25. The tops of the word line conductors 25 are covered with the insulators 26.

As illustrated in FIG. 11, the mask 69 and the oxide 61 are removed, and the transistor 31 is formed. The formation of the transistor 31 includes the introduction of impurities for the channel of the transistor 31, formation of the gate structure (the set of the gate oxide 32, the gate electrode 33, the nitride 34) and nitride 34, and ion implantation for forming the source or drain areas 31sd. The formation of the gate structure and the nitride 34 includes deposition of the set of a film for the gate oxide 32, a film for the gate electrode 33, a film for the nitride 34, and patterning of the deposited films. With the ion implantation for forming the source or drain areas 31sd of the transistor 31 or another step, the source or drain areas STsd of the select transistors 23 are formed. On the surface of the entire structure obtained by the process so far, the oxide 41 is deposited, and the nitride 42 is deposited on the oxide 41. Parts of the nitride 42 where the contacts 36 will be formed are formed with holes 70 by a lithography step and RIE.

As illustrated in FIG. 12, the oxide 43 is deposited on the surface of the entire structure obtained by the process so far. In the positions of the holes 70, the oxide is located on the oxide 41. The nitride 44 is then deposited on the oxide 43, and a part 55a of the interlayer insulator 55 is deposited on the nitride 44. The part 55a of the interlayer insulator 55 is, for example, a pre-metal dielectric (PMD), is higher than the nitride 44 on gate structure, and has substantially the same height as the source line films 45.

As illustrated in FIG. 13, areas of the interlayer dielectric 55a where the source line films 45 will be formed are removed by etching with ion beams to form trenches 72. The etching stops at the nitride 44 to expose the nitride 44 at the bottoms of the trenches 72.

As illustrated in FIG. 14, the parts of the nitride 44 at the bottoms of the trenches 72 are removed by the RIE. As a result, the parts of the oxides 43 at the bottoms of the trenches 72 are exposed. The sections of the oxide 43 at the bottoms of the trenches 72 are then removed by the RIE. The etching stops at the nitride 42 to expose the nitride 42 at the bottoms of the trenches 72. In contrast, the areas where the contacts 36 will be formed are free from the nitride 42, and the oxide 41 is located under the oxide 43. For this reason, the etching for the oxide 43 does not stop at the completion of removal of the oxide 43 in the areas where the contacts 36 will be formed, and removes the oxide 41 as well. As a result, in the areas of the trenches 72 where the contacts 36 will be formed, holes are formed and the surface of the substrate 21 is exposed at the bottoms of the holes 73.

As illustrated in FIG. 6, a conductor for the source line films 45 is deposited in the trenches 72 to form the source line films 45. During this formation, the conductor is also deposited in the holes 73 to form the contacts 36. A second section of the interlayer dielectric 55 is then deposited on the section 55a of the interlayer insulator 55 to the height where the bottoms of the MTJ elements M will be located by a known method. In the section 55a and the second section of the interlayer insulator 55, trenches for the lower electrodes 38 are formed, and a conductor is formed in the trenches to form the lower electrodes 38.

On the lower electrodes 38, the MTJ elements M are formed by a known method. The formation of the MTJ elements M includes heating the MTJ elements M, and by extension heating the structure obtained by the process up to this point at a high temperature. This annealing is performed in order to improve the crystallinity of the layers SL, FL, and SCL in the MTJ elements M. Subsequently, the upper electrodes 47 and 51, the conductive films 52, and the further section of the interlayer dielectric 55 are formed to obtain the structure of the memory device 1.

Incidentally, structures of the cell array 11 are described in U.S. Patent application publication 2012/0286339 titled “SEMICONDUCTOR STORAGE DEVICE”, the entire contents of which are incorporated herein by reference.

(Advantages)

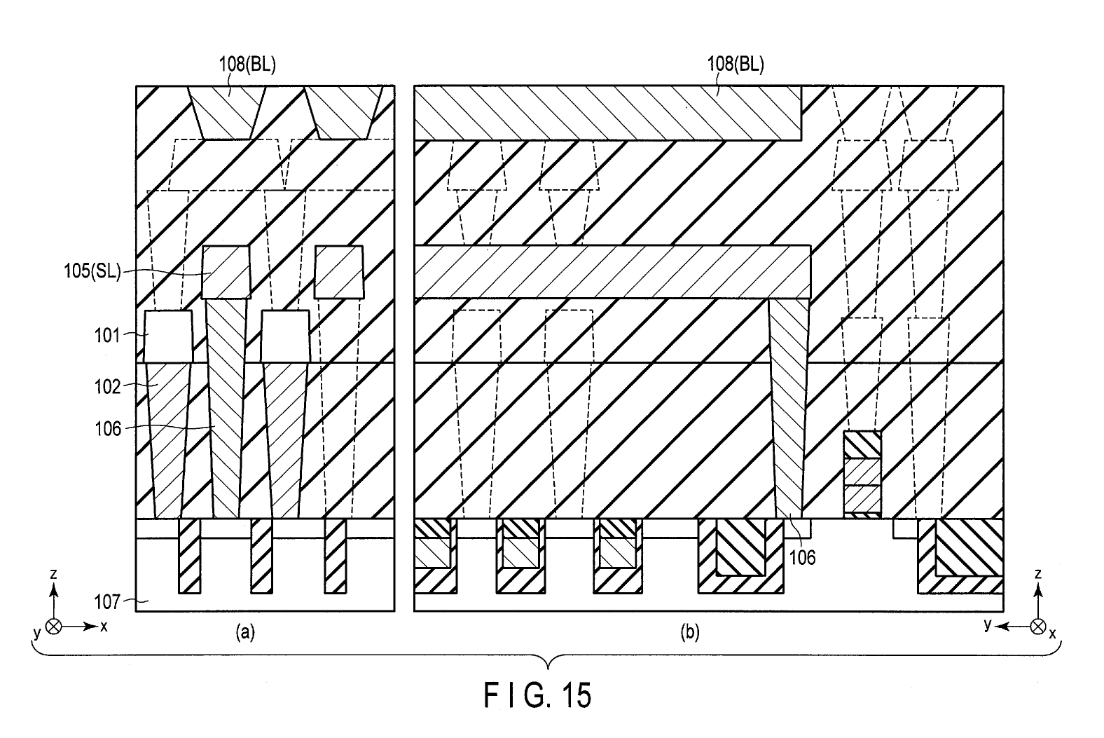

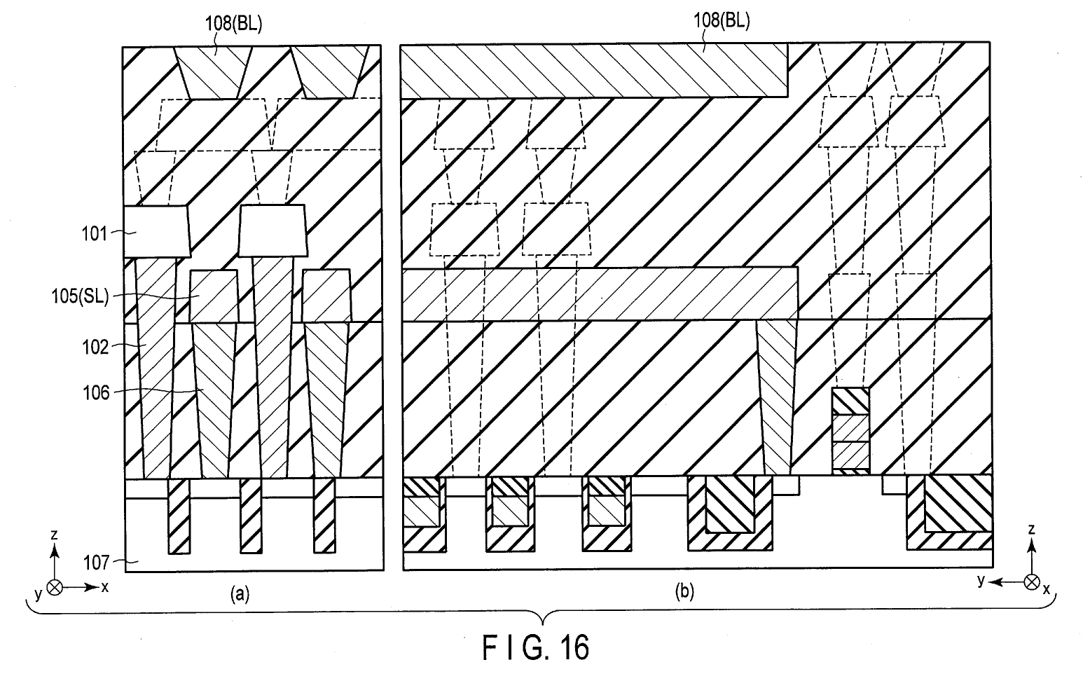

The cell array 11 of the memory device 1 of FIGS. 1 and 2 can be implemented by the structure illustrated in FIG. 15 or FIG. 16. FIGS. 15 and 16 schematically illustrate cross sections of a part of the structure of the cell array. FIG. 15(a) and FIG. 15(b) illustrate the cross sections which perpendicularly intersect each other, and FIG. 16(a) and FIG. 16(b) illustrate the cross sections which perpendicularly intersect each other.

As illustrated in FIG. 15, conductors 105 serving as source lines (source line films) are located in a level (layer) higher, along the z-axis, than the MTJ elements 101. Contacts 106 are provided between the source line films 105 and a substrate 107. Conductors 108 serving as bit lines are located above the source line films 105. For forming the FIG. 15 structure, the source line films 105 are formed after formation of the MTJ elements 101.

Copper (Cu) has a low resistance, and, therefore, forming the source line films 105 with Cu can implement the source lines with a low resistance. Cu is, however, weak against high temperatures, and specifically when Cu has a high temperature, the molecules of Cu condense. The condensation degrades the flatness of a Cu film, and/or the Cu film breaks apart, which breaks the lines implemented by the Cu film. In contrast, formation of the MTJ elements 101 generally requires the MTJ elements 101 to be put in an atmosphere of a relatively high temperature. With the FIG. 15 structure, the source line films 105 are formed after the formation of the MTJ elements 101, and, therefore, the source line films 105 are not exposed to a high-temperature environment for formation of the MTJ elements 101. This allows for the source line films 105 to be formed with Cu.

In contrast, lower electrodes 106 are located adjacent to the MTJ elements 101 as can be seen from FIG. 15. Therefore, the MTJ elements 101 cannot have a large area in the xy-plane. A larger distance between an MTJ element 101 and a lower electrode 106 can increase the size of the MTJ elements 101; however this reduces the density of the MTJ elements 106 in the xy-plane.

In contrast, in the FIG. 16 structure, the source line films 105 are located along the z-axis in a level lower than the MTJ elements 101. Because of this, no components, such as the source line films 105 and contacts 106, are provided around the MTJ elements 101. This allows for large MTJ elements 101. However, in order for the FIG. 16 structure to be formed, the source line films 105 are formed before the formation of the MTJ elements 101, and, therefore, the source line films 105 are exposed to the high-temperature environment for formation of the MTJ elements 101. Due to this, the source line films 105 cannot be formed with Cu. In other words, low resistance source lines using Cu cannot be implemented.

The structure of the memory device 1 of one embodiment includes the MTJ elements M in a level higher than the source line films 45; therefore, no contacts for coupling the source line films 45 and the substrate 21, such as contacts 106 of FIG. 16, need to be provided adjacent to the MTJ elements M. This allows the MTJ elements M to have large areas in the xy-plane. An MTJ element M of a large area enables its shift control layer SCL to have a large area. The larger the shift control layer SCL, the larger the magnetic field formed by the shift control layer SCL, and thus the higher the ability of the shift control layer SCL to cancel the magnetic field that the storage layer FL of the MTJ element M that includes that shift control layer SCL is placed in. Therefore, a larger shift control layer SCL can more strongly suppress unintentional flipping of the magnetization orientation of the storage layer which would otherwise occur due to the magnetic field formed by the MTJ element M that includes that shift control layer or another MTJ element M.

Moreover, the source line films 45 include a material which can endure a temperature in the heat treatment for formation of the MTJ elements M, and includes, for example, W as described above. Furthermore, the source line films 45 have high aspect ratios in the cross section of FIG. 6(a), and spread in the yz-plane to have plate shapes. For this reason, the source line films 45 have resistances lower than in a case of low aspect ratios as in the structure of FIG. 14 or FIG. 15. W has a resistance higher than Cu, and by using W, it is not possible for the source line films 45 to have low resistances, as would be possible through the use of Cu, due to the selection of materials. Using W and the high aspect ratios can, however, implement the source line films 45 which can endure the high-temperature processing for the MTJ elements M and which have low resistances.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a substrate;
a first conductor above the substrate;
a first transistor whose one of a source and a drain is coupled to the first conductor;
a memory element which is provided above a top of the first conductor, has one of switchable resistances, and is coupled at a first end to the other of the source and the drain of the first transistor; and
a second transistor which is provided above the substrate and has a gate electrode having a height lower than a top of the first conductor.

2. The device of claim 1, wherein
the first conductor has an aspect ratio of five or higher.

3. The device of claim 1, wherein
the first conductor includes tungsten over a bottom and a top.

4. The device of claim 1, further comprising:
a second conductor above the first conductor,
wherein the memory element is coupled at a second end to the second conductor through a conductive material.

5. The device of claim 1, wherein:
the first conductor extends along a first axis, and
the memory element is isolated in a first plane which includes the first axis and a second axis perpendicular to the first axis.

6. The device of claim 5, further comprising:
an electrode between the first end of the memory element and the other of the source and the drain of the first transistor,
wherein the first conductor and the electrode adjoin each other.

7. The device of claim 1, wherein
the memory element comprises:
a first magnetic layer;
a second magnetic layer which has a coercivity higher than a coercivity of the first magnetic layer; and
a third magnetic layer which is provided at a side of the second magnetic layer opposite to the first magnetic layer and has a coercivity higher than the coercivity of the second magnetic layer.

8. A memory device comprising:
a substrate;
a first conductor above the substrate;
a first transistor whose one of a source and a drain is coupled to the first conductor;
a memory element which is provided above a top of the first conductor, is coupled at a first end to the other of the source and the drain of the first transistor, and comprises two magnetic layers and a nonmagnetic layer between the two magnetic layers; and
a second transistor which is provided above the substrate and has a gate electrode having a height lower than a top of the first conductor.

9. The device of claim 8, wherein
the first conductor has an aspect ratio of five or higher.

10. The device of claim 8, wherein
the first conductor includes tungsten over a bottom and a top.

11. The device of claim 8, further comprising:
a second conductor above the first conductor,
wherein the memory element is coupled at a second end to the second conductor through a conductive material.

12. The device of claim 8, wherein:
the first conductor extends along a first axis, and
the memory element is isolated in a first plane which includes the first axis and a second axis perpendicular to the first axis.

13. The device of claim 12, further comprising:
an electrode between the first end of the memory element and the other of the source and the drain of the first transistor,
wherein the first conductor and the electrode adjoin each other.

14. The device of claim 8, wherein
one of the two magnetic layers comprises a first magnetic layer,
the other of the two magnetic layers comprises a second magnetic layer which has a coercivity higher than a coercivity of the first magnetic layer; and
the device further comprises a third magnetic layer which is provided at a side of the second magnetic layer opposite to the first magnetic layer and has a coercivity higher than the coercivity of the second magnetic layer.

15. A method of manufacturing a memory device comprising:
forming a transistor which has a source and a drain on a substrate;
forming an insulator on the substrate;
forming a trench which is partly in contact with one of the source and the drain;
forming a first conductor in the trench;
forming a second conductor which is in contact with the other of the source and the drain after the forming of the first conductor; and
forming a memory element on the second conductor.

16. The method of claim 15, wherein
the trench has an aspect ratio of five or larger.

17. The method of claim 15, wherein
the forming of the first conductor comprises forming the first conductor from an opening of the trench to a bottom of the trench.

18. The method of claim 15, wherein
the first conductor comprises tungsten.

19. The method of claim 15, wherein
the forming of the memory element comprises heating the memory element.

20. The method of claim 15, wherein
the memory element comprises:
a first magnetic layer;
a second magnetic layer which has a coercivity higher than a coercivity of the first magnetic layer; and
a third magnetic layer which is provided at a side of the second magnetic layer opposite to the first magnetic layer and has a coercivity higher than the coercivity of the second magnetic layer.
